(19) United States
(12) Patent Application Publication
(10) Pub. No.: US 2026/0287631 A1
(43) Pub. Date: Sep. 24, 2026

(54) APPARATUS AND METHOD FOR ELECTROMAGNETIC SIDE-CHANNEL LEAKAGE LOCALIZATION ON PROCESSORS

(71) Applicant: AGENCY FOR DEFENSE DEVELOPMENT, Daejeon (KR)

(72) Inventors: Changmin JEONG, Daejeon (KR); Daehyeon BAE, Seoul (KR); Hakchul SHIN, Incheon (KR); Seokhie HONG, Seoul (KR)

(21) Appl. No.: 19/549,071

(22) Filed: Mar. 13, 2026

(30) Foreign Application Priority Data
Feb. 25, 2025 (KR) 10-2025-0024646

(51) Int. Cl. G01R 29/08; G01R 31/00

(52) U.S. Cl. CPC G01R 29/0878; G01R 29/0871; G01R 31/002

(57) ABSTRACT

An apparatus for electromagnetic side-channel leakage localization may include a probe configured to measure an electromagnetic wave signal while moving over an upper surface of an integrated circuit (IC) chip based on a searching grid when the IC chip executes a command gadget in the form of a specific command being repeated at a fixed clock cycle, a spectrum analyzer configured to measure a power density of a sideband peak of amplitude modulation, by using the electromagnetic wave signal, and create a leakage map with respect to a surface of the IC chip, and a leakage point analyzer configured to estimate a side-channel leakage point of the IC chip by analyzing the leakage map.

### CROSS-REFERENCE TO RELATED APPLICATION

This application claims priority to and the benefit of Korean Patent Application No. 10-2025-0024646 filed with the Korean Intellectual Property Office on Feb. 25, 2025, the entire contents of which are incorporated herein by reference.

### BACKGROUND

### (a) Field

The present disclosure relates to an apparatus and method for electromagnetic side-channel leakage localization on processors.

### (b) Description of the Related Art

Due to the physical characteristics of integrated circuits (ICs), information leakage that is not intended by the system designer may occur during operation, and this is called side-channel leakage. The side-channel leakage can reveal secret information such as internal states or encryption keys through statistical methods, and this method is called side-channel analysis. Typical examples of side-channel leakage include power consumption information, electromagnetic wave radiation, heat generation, photon emission. Among these, electromagnetic wave subchannel analysis is being actively studied as the most realistic and efficient method.

For electromagnetic wave side-channel analysis, signals must be collected from the surface of IC by using a probe. However, the coil diameter of the probe is generally smaller than the size of the package or silicon die of the integrated circuit, and side-channel leakage occurs at a local location on the surface of the IC chip, so the exact leakage location must be searched. This becomes more important as the integrated circuit being analyzed becomes more complex and advanced.

Numerous studies have been conducted to explore the location of electromagnetic wave side-channel leakage, but there are many limitations in terms of the limitations, realism, and performance of the system to be analyzed, which makes its feasibility low. Limitations include requiring control over an analysis target processor, being applicable only to cryptographic implementations, being applicable only to low-end processors, and being inapplicable to dynamic frequency scaling and multi-core systems.

### SUMMARY

The present disclosure attempts to provide an apparatus and method for electromagnetic side-channel leakage localization on processors that can solve the above-described limitations.

An apparatus for electromagnetic side-channel leakage localization may include a probe configured to measure an electromagnetic wave signal while moving over an upper surface of an integrated circuit (IC) chip based on a searching grid when the IC chip executes a command gadget in the form of a specific command being repeated at a fixed clock cycle, a spectrum analyzer configured to measure a power density of a sideband peak of amplitude modulation, by using the electromagnetic wave signal, and create a leakage map with respect to a surface of the IC chip, and a leakage point analyzer configured to estimate a side-channel leakage point of the IC chip by analyzing the leakage map.

A frequency of the sideband peak may be calculated by an equation

$${f}_{clk} \pm n \frac{{f}_{clk}}{c} ,$$

where f_{clk} is an operation frequency of the IC chip, c is the number of repeating clock cycles of the command gadget, and nis a natural number.

The leakage map may represent a distribution of the power density of the sideband peak of amplitude modulation on the surface of the IC chip.

The leakage point analyzer may estimate a portion of the leakage map where the power density of the sideband peak of amplitude modulation is greater than or equal to a reference value as the side-channel leakage point.

The apparatus may further include an IC mounting section configured to supply power for driving of the IC chip.

The apparatus may further include a command input section storing the command gadget, and configured to input the command gadget into the IC chip to cause the IC chip to execute the command gadget.

A method for electromagnetic side-channel leakage localization may include executing a command gadget in the form of a specific command being repeated at a fixed clock cycle, by an integrated circuit (IC) chip, measuring an electromagnetic wave signal while moving over an upper surface of the IC chip based on a searching grid, by a probe, measuring a power density of a sideband peak of amplitude modulation, by using the electromagnetic wave signal, by a spectrum analyzer, creating a leakage map with respect to a surface of the IC chip, by the spectrum analyzer, and estimating a side-channel leakage point of the IC chip by analyzing the leakage map, by a leakage point analyzer.

A frequency of the sideband peak may be calculated by an equation

$${f}_{clk} \pm n \frac{{f}_{clk}}{c} ,$$

where f_{clk} is an operation frequency of the IC chip, c is the number of repeating clock cycles of the command gadget, and n is a natural number.

The leakage map may represent a distribution of the power density of the sideband peak of amplitude modulation on the surface of the IC chip.

An apparatus for electromagnetic side-channel leakage localization may include a signal generator configured to input an input signal of a specific frequency into an input terminal including a power supply rail of an integrated circuit (IC) chip or an element connected to the power supply rail, a probe configured to measure an electromagnetic wave signal while moving over an upper surface of the IC chip based on a searching grid when intermodulation distortion between an operation clock of the IC chip and the input signal occurs, a spectrum analyzer configured to measure a power density of an intermodulation distortion peak by using the electromagnetic wave signal, and create a leakage map with respect to a surface of the IC chip, and a leakage point analyzer configured to estimate a side-channel leakage point of the IC chip by analyzing the leakage map.

A frequency of the intermodulation distortion peak may be calculated by an equation f_{clk}±nfᵢₙⱼ where f_{clk} is an operation frequency of the IC chip, fᵢₙⱼ is a frequency of the input signal, and n is a natural number.

The leakage map may represent a distribution of a power density of the intermodulation distortion peak on the surface of the IC chip.

The leakage point analyzer may estimate a portion of the leakage map where a power density of the intermodulation distortion peak is greater than or equal to a reference value as the side-channel leakage point.

The apparatus may further include an IC mounting section configured to supply power for driving of the IC chip.

The input signal may include a sine wave or square wave of the specific frequency.

A method for electromagnetic side-channel leakage localization may include inputting an input signal of a specific frequency into an input terminal including a power supply rail of an integrated circuit (IC) chip or an element connected to the power supply rail, by a signal generator, measuring an electromagnetic wave signal while moving over an upper surface of the IC chip based on a searching grid, when intermodulation distortion between an operation clock of the IC chip and the input signal occurs, by a probe, measuring a power density of an intermodulation distortion peak by using the electromagnetic wave signal, by a spectrum analyzer, creating a leakage map with respect to a surface of the IC chip, by the spectrum analyzer, and estimating a side-channel leakage point of the IC chip by analyzing the leakage map, by a leakage point analyzer.

A frequency of the intermodulation distortion peak may be calculated by an equation f_{clk}±nfᵢₙⱼ, where f_{clk} is an operation frequency of the IC chip, fᵢₙⱼ is a frequency of the input signal, and n is a natural number.

The leakage map may represent a distribution of a power density of the intermodulation distortion peak on the surface of the IC chip.

An apparatus and method for electromagnetic side-channel leakage localization on processors according to an embodiment of the present disclosure are applicable to complex processors (SoCs) other than microcontroller-level processors, are applicable to general-purpose systems in addition to cryptographic systems, are capable of creating leakage maps for multi-core systems, are capable of creating leakage maps for systems to which dynamic frequency scaling is applied, and are capable of detecting leakage at a faster speed than existing studies.

### BRIEF DESCRIPTION OF THE DRAWINGS

FIG. 1 is a block diagram representing an apparatus for electromagnetic side-channel leakage localization of a processor according to an embodiment of the present disclosure.

FIG. 2 is a flowchart representing a method for electromagnetic side-channel leakage localization of a processor according to an embodiment of the present disclosure.

FIG. 3 represents an example of a command gadget according to an embodiment of the present disclosure.

FIG. 4 represents an example of a leakage map created by using a method for electromagnetic side-channel leakage localization on processors according to an embodiment of the present disclosure.

FIG. 5 is a block diagram representing an apparatus for electromagnetic side-channel leakage localization on processors according to another embodiment of the present disclosure.

FIG. 6 is a flowchart representing a method for electromagnetic side-channel leakage localization on processors according to another embodiment of the present disclosure.

FIG. 7 represents an example of a leakage map created by using a method for electromagnetic side-channel leakage localization on processors according to another embodiment of the present disclosure.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Parts that are irrelevant to the description will be omitted to clearly describe the present disclosure, and the same elements will be designated by the same reference numerals throughout the specification.

Unless explicitly described to the contrary, the word “comprise”, and variations such as “comprises” or “comprising”, will be understood to imply the inclusion of stated elements but not the exclusion of any other elements.

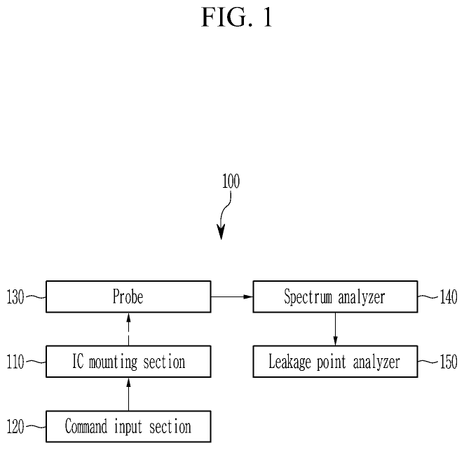

Hereinafter, an apparatus and method for electromagnetic side-channel leakage localization on processors according to an embodiment of the present disclosure will be described with reference to FIG. 1 to FIG. 4.

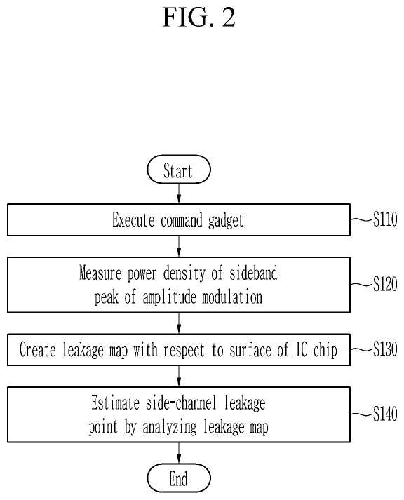

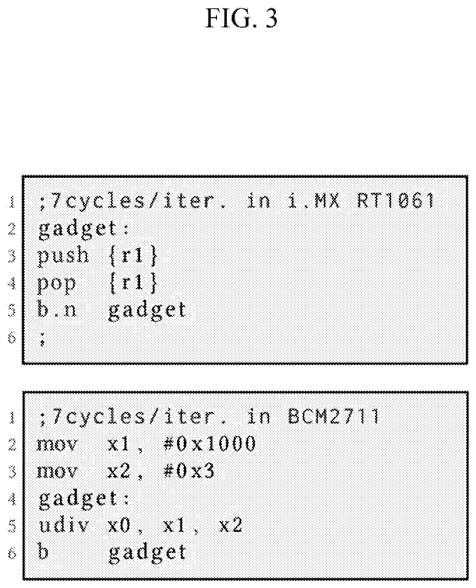

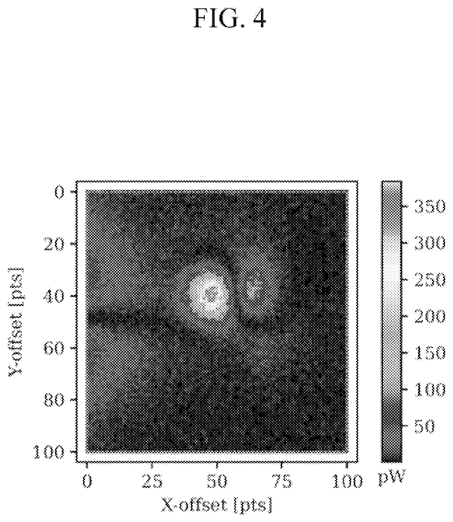

FIG. 1 is a block diagram representing an apparatus for electromagnetic side-channel leakage localization of a processor according to an embodiment of the present disclosure. FIG. 2 is a flowchart representing a method for electromagnetic side-channel leakage localization of a processor according to an embodiment of the present disclosure. FIG. 3 represents an example of a command gadget according to an embodiment of the present disclosure. FIG. 4 represents an example of a leakage map created by using a method for electromagnetic side-channel leakage localization on processors according to an embodiment of the present disclosure.

Referring to FIGS. 1 to 4, an apparatus 100 for electromagnetic side-channel leakage localization on processors according to an embodiment of the present disclosure may include an integrated circuit (IC) mounting section 110, a command input section 120, a probe 130, a spectrum analyzer 140 and a leakage point analyzer 150.

The IC mounting section 110 may mount an IC chip (or processor) of an analysis target. The IC mounting section 110 may serve to connect the command input section 120 and the IC chip. The IC mounting section 110 may serve to supply power for driving of the IC chip. The IC chip may include a system on chip (SoC).

As exampled in FIG. 3, the command input section 120 may store software (hereinafter, a command gadget) in the form of a specific command being repeated at a fixed clock cycle. The command input section 120 may input the command gadget into the IC chip to cause the IC chip to execute the command gadget. That is, the IC chip may execute the command gadget inputted from the command input section 120, at step S110. When the IC chip executes the command gadget, amplitude modulation and a sideband peak may occur in the electromagnetic wave side-channel signal of the IC chip. The sideband peak is a result of signal distortion occurring in the frequency domain as a result of the amplitude modulation, and a new frequency component due to signal distortion is included in the original signal. The frequency of the sideband peak may be calculated by the Equation 1 below.

$${f}_{clk} \pm n \frac{{f}_{clk}}{c} \qquad ( Equation 1 )$$

Here, f_{clk} is an operation frequency of a processor core (IC chip), c is the number of repeating clock cycles of the command gadget, n is a natural number.

On the other hand, when the IC chip is configured as a processor module that is capable of supplying power on its own and inputting the command gadget, the IC mounting section 110 and the command input section 120 may be omitted.

The probe 130 may include a near-field probe that can measure an electromagnetic wave signal. The probe 130 may be moved and located in X-axis, Y-axis and Z-axis directions based on a searching grid on an upper surface of the IC chip. To this end, the probe 130 may include a X-axis motor that can enable precise movement in the X-axis direction, a Y-axis motor that can enable precise movement in the Y-axis direction, and a Z-axis motor that can enable precise movement in the Z-axis direction. The probe 130 can precisely move in the X-axis, Y-axis and Z-axis directions by using the X-axis motor, the Y-axis motor and the Z-axis motor. The probe 130 may measure the electromagnetic wave signal with respect to all portions of the IC chip while moving over the upper surface of the IC chip based on the searching grid when the IC chip executes the command gadget, and transfer it to the spectrum analyzer 140.

The spectrum analyzer 140 may measure a power density of a sideband peak of amplitude modulation occurring when the IC chip executes the command gadget by using the electromagnetic wave signal transferred through the probe 130, at step S120. The spectrum analyzer 140 may measure the power density of the sideband peak of amplitude modulation, by Fourier transforming the electromagnetic wave signal.

The spectrum analyzer 140 may measure the power density of the sideband peak of amplitude modulation in all portions of the surface of the IC chip through the probe 130 moving above the upper surface of the IC chip, and as exampled in FIG. 4, may create the leakage map with respect to the surface of the IC chip, at step S130. The leakage map may represent the distribution of the power density of the sideband peak of amplitude modulation on the surface of the IC chip.

The leakage point analyzer 150 may estimate a side-channel leakage point of the IC chip by analyzing the leakage map, at step S140. For example, the leakage point analyzer 150 may estimate a portion of the leakage map where the power density of the sideband peak of amplitude modulation is greater than or equal to a reference value as the side-channel leakage point. Alternatively, the leakage point analyzer 150 may estimate the side-channel leakage point in the leakage map based on the result learned by machine-learning or machine learning.

As such, the apparatus 100 for electromagnetic side-channel leakage localization on processors according to an embodiment of the present disclosure may estimate the side-channel leakage point by causing the IC chip (or processor) to perform a command of a particular form, and creating the leakage map by observing the sideband peak of the amplitude modulation that occurs as a result. This method may be referred to as a passive method using amplitude modulation characteristics.

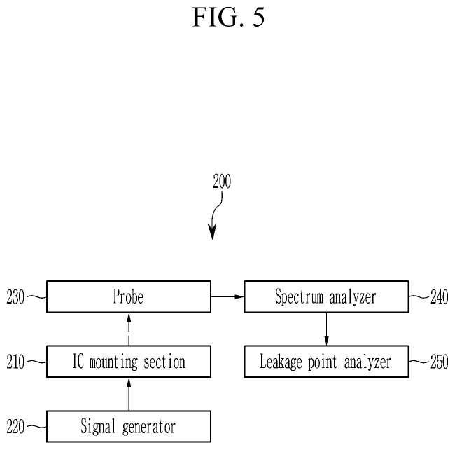

Hereinafter, an apparatus and method for electromagnetic side-channel leakage localization on processors according to another embodiment of the present disclosure will be described with reference to FIG. 5 to FIG. 7.

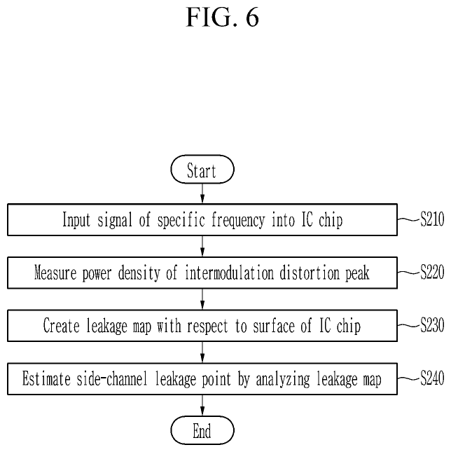

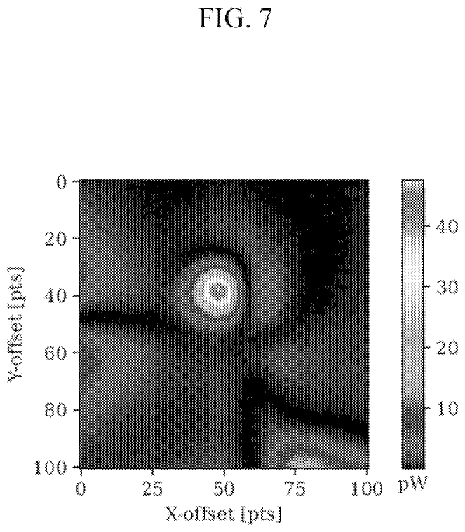

FIG. 5 is a block diagram representing an apparatus for electromagnetic side-channel leakage localization on processors according to another embodiment of the present disclosure. FIG. 6 is a flowchart representing a method for electromagnetic side-channel leakage localization on processors according to another embodiment of the present disclosure. FIG. 7 represents an example of a leakage map created by using a method for electromagnetic side-channel leakage localization on processors according to another embodiment of the present disclosure.

Referring to FIGS. 5 to 7, an apparatus for electromagnetic side-channel leakage localization 200 on processors according to another embodiment of the present disclosure may include an integrated circuit (IC) mounting section 210, a signal generator 220, a probe 230, a spectrum analyzer 240 and a leakage point analyzer 250.

The IC mounting section 210 may mount the IC chip (or processor) of the analysis target, and serve to connect an output terminal of the signal generator 220 to an input terminal of the IC chip. The IC mounting section 210 may serve to supply power for driving of the IC chip, and the IC chip may include a system on chip (SoC).

The signal generator 220 may generate a signal of a specific frequency and output it to the input terminal of the IC chip. That is, the signal generator 220 may input the signal of the specific frequency into the IC chip, at step S210. The input terminal of the IC chip may include an element connected to a power supply rail or the power supply rail of the IC chip (processor core). The signal of the specific frequency may include a sine wave or square wave of the specific frequency, as an input signal for intermodulation distortion (IMD). The signal generator 220 may include a signal generator, a pulse generator, a function generator, or the like, that can generate a sine wave or square wave of a specific frequency in response to an input of the specific frequency.

When the signal of the specific frequency is inputted into the IC chip, intermodulation distortion between an operation clock of the IC chip and the input signal may occur. The intermodulation distortion is a type of nonlinear distortion, which is signal distortion that occurs when signals having two or more different frequencies is injected into a nonlinear circuit due to mutual influence between signals. As a result of the intermodulation distortion between the operation clock of the IC chip and the input signal of the specific frequency, an intermodulation distortion peak may occur in the frequency domain. Due to the intermodulation distortion, a new frequency component is included in the original signal. The frequency of the intermodulation distortion peak may be calculated by the Equation 2 below.

$${f}_{clk} \pm {nf}_{inj} \qquad ( Equation 2 )$$

Here, f_{clk} is an operation frequency of a processor core, fᵢₙⱼ is a frequency of an injected input signal, and n is a natural number.

When the input signal of the specific frequency is injected into the IC chip and the intermodulation distortion occurs, the probe 230 may measure the electromagnetic wave signal with respect to all portions of the IC chip while moving over the upper surface of the IC chip based on the searching grid, to transfer it to the spectrum analyzer 240. The probe 230 may include the same configurational features as the configurational features of the probe 130 described above with reference to FIG. 1 to FIG. 4, and a redundant description thereof is not included herein.

The spectrum analyzer 240 may measure the power density of the intermodulation distortion peak occurring in the IC chip by using the electromagnetic wave signal transferred through the probe 230, at step S220. The spectrum analyzer 240 may measure the power density of the intermodulation distortion peak by Fourier transforming the electromagnetic wave signal.

The spectrum analyzer 240 may measure the power density of the intermodulation distortion peak in all portions of the surface of the IC chip by using the electromagnetic wave signal transferred through the probe 230, and as exampled in FIG. 7, may create the leakage map with respect to the surface of the IC chip, at step S230. The leakage map may represent the distribution of the power density of the intermodulation distortion peak on the surface of the IC chip.

The leakage point analyzer 250 may estimate the side-channel leakage point by analyzing the leakage map, at step S240. For example, the leakage point analyzer 250 may estimate a portion where the power density of the intermodulation distortion peak on the leakage map is greater than or equal to the reference value as the side-channel leakage point. Alternatively, the leakage point analyzer 250 may estimate the side-channel leakage point in the leakage map based on the result learned by machine-learning or machine learning.

As such, an apparatus for electromagnetic side-channel leakage localization 200 on processors according to another embodiment of the present disclosure may estimate the side-channel leakage point by artificially injecting the input signal of the specific frequency into the IC chip (or processor), and creating the leakage map by observing the intermodulation distortion peak, which is a result of the intermodulation distortion that occurs as a result. This method may be referred to as an active method using intermodulation distortion characteristics.

The embodiments of the present disclosure are described, but the accompanying drawings and the detailed description of the present disclosure described above are just used for the purpose of describing the present disclosure and are not used for qualifying the meaning or limiting the scope of the present disclosure, which is disclosed in the appended claims. Therefore, it will be appreciated to those skilled in the art that various modifications are made and other equivalent embodiments are available. Accordingly, the actual technical protection scope of the present disclosure must be determined by the spirit of the appended claims.

What is claimed is:

1. An apparatus for electromagnetic side-channel leakage localization, the apparatus comprising:
a probe configured to measure an electromagnetic wave signal while moving over an upper surface of an integrated circuit (IC) chip based on a searching grid when the IC chip executes a command gadget in the form of a specific command being repeated at a fixed clock cycle;
a spectrum analyzer configured to measure a power density of a sideband peak of amplitude modulation, by using the electromagnetic wave signal, and create a leakage map with respect to a surface of the IC chip; and
a leakage point analyzer configured to estimate a side-channel leakage point of the IC chip by analyzing the leakage map.

2. The apparatus of claim 1, wherein a frequency of the sideband peak is calculated by an equation
$${f}_{clk} \pm n \frac{{f}_{clk}}{c} ,$$
wherein f_{clk} is an operation frequency of the IC chip, c is the number of repeating clock cycles of the command gadget, and n is a natural number.

3. The apparatus of claim 1, wherein the leakage map represents a distribution of the power density of the sideband peak of amplitude modulation on the surface of the IC chip.

4. The apparatus of claim 1, wherein the leakage point analyzer estimates a portion of the leakage map where the power density of the sideband peak of amplitude modulation is greater than or equal to a reference value as the side-channel leakage point.

5. The apparatus of claim 1, further comprising an IC mounting section configured to supply power for driving of the IC chip.

6. The apparatus of claim 1, further comprising a command input section storing the command gadget, and configured to input the command gadget into the IC chip to cause the IC chip to execute the command gadget.

7. A method for electromagnetic side-channel leakage localization, the method comprising:
executing a command gadget in the form of a specific command being repeated at a fixed clock cycle, by an integrated circuit (IC) chip;
measuring an electromagnetic wave signal while moving over an upper surface of the IC chip based on a searching grid, by a probe;
measuring a power density of a sideband peak of amplitude modulation, by using the electromagnetic wave signal, by a spectrum analyzer;
creating a leakage map with respect to a surface of the IC chip, by the spectrum analyzer; and
estimating a side-channel leakage point of the IC chip by analyzing the leakage map, by a leakage point analyzer.

8. The method of claim 7, wherein a frequency of the sideband peak is calculated by an equation
$${f}_{clk} \pm n \frac{{f}_{clk}}{c} ,$$
wherein f_{clk} is an operation frequency of the IC chip, c is the number of repeating clock cycles of the command gadget, and n is a natural number.

9. The method of claim 7, wherein the leakage map represents a distribution of the power density of the sideband peak of amplitude modulation on the surface of the IC chip.

10. An apparatus for electromagnetic side-channel leakage localization, the apparatus comprising:
a signal generator configured to input an input signal of a specific frequency into an input terminal comprising a power supply rail of an integrated circuit (IC) chip or an element connected to the power supply rail;
a probe configured to measure an electromagnetic wave signal while moving over an upper surface of the IC chip based on a searching grid when intermodulation distortion between an operation clock of the IC chip and the input signal occurs;
a spectrum analyzer configured to measure a power density of an intermodulation distortion peak by using the electromagnetic wave signal, and create a leakage map with respect to a surface of the IC chip; and
a leakage point analyzer configured to estimate a side-channel leakage point of the IC chip by analyzing the leakage map.

11. The apparatus of claim 10, wherein a frequency of the intermodulation distortion peak is calculated by an equation f_{clk}±nfᵢₙⱼ,
wherein f_{clk} is an operation frequency of the IC chip, fᵢₙⱼ is a frequency of the input signal, and n is a natural number.

12. The apparatus of claim 10, wherein the leakage map represents a distribution of a power density of the intermodulation distortion peak on the surface of the IC chip.

13. The apparatus of claim 10, wherein the leakage point analyzer estimates a portion of the leakage map where a power density of the intermodulation distortion peak is greater than or equal to a reference value as the side-channel leakage point.

14. The apparatus of claim 10, further comprising an IC mounting section configured to supply power for driving of the IC chip.

15. The apparatus of claim 10, wherein the input signal comprises a sine wave or square wave of the specific frequency.

16. A method for electromagnetic side-channel leakage localization, the method comprising:
inputting an input signal of a specific frequency into an input terminal comprising a power supply rail of an integrated circuit (IC) chip or an element connected to the power supply rail, by a signal generator;
measuring an electromagnetic wave signal while moving over an upper surface of the IC chip based on a searching grid, when intermodulation distortion between an operation clock of the IC chip and the input signal occurs, by a probe;
measuring a power density of an intermodulation distortion peak by using the electromagnetic wave signal, by a spectrum analyzer;
creating a leakage map with respect to a surface of the IC chip, by the spectrum analyzer; and
estimating a side-channel leakage point of the IC chip by analyzing the leakage map, by a leakage point analyzer.

17. The method of claim 16, wherein a frequency of the intermodulation distortion peak is calculated by an equation f_{clk}±nfᵢₙⱼ,
wherein f_{clk} is an operation frequency of the IC chip, fᵢₙⱼ is a frequency of the input signal, and n is a natural number.

18. The method of claim 16, wherein the leakage map represents a distribution of a power density of the intermodulation distortion peak on the surface of the IC chip.
